(19) United States
(12) Patent Application Publication
(10) Pub. No.: US 2006/0145204 A1
(43) Pub. Date: Jul. 6, 2006

(54) CMOS image sensor and method for fabricating the same

(76) Inventor: Sun Wook Jung, Yeoju-gun (KR)

Correspondence Address: MCKENNA LONG & ALDRIDGE LLP;Song K. Jung, 1900 K Street, N.W., Washington, DC, 20006, US

(21) Appl. No.: 11/319,488

(22) Filed: Dec. 29, 2005

(30) Foreign Application Priority Data
Dec. 30, 2004 (KR) 2004-0116477

(51) Int. Cl. H01L 31/113

(52) U.S. Cl. 257/291

(57) ABSTRACT

A CMOS image sensor includes a passivation layer including an etch stop layer, the passivation layer having a color filter array pattern formed to a depth determined by the etch stop layer, the color filter array pattern including separately defined color filter regions; and a color filter array including a plurality of color filters for respectively filtering light according to color, the color filters being formed according to the color filter array pattern, each color filter formed of a material filling only a corresponding color filter region.

### CROSS-REFERENCE TO RELATED APPLICATIONS

This application claims the benefit of Korean Patent Application No. 0116477, filed on Dec. 30, 2004, which is hereby incorporated by reference as if fully set forth herein.

### BACKGROUND OF THE INVENTION

1. Field of the Invention

The present invention relates to an image sensor, and more particularly, to a complementary metal-oxide-semiconductor (CMOS) image sensor in which a color filter material fills an etched portion of a nitride film.

2. Discussion of the Related Art

An image sensor is a semiconductor device for converting an optical image to an electrical signal, and can be a charge-coupled device or a complementary metal-oxide-silicon (CMOS) image sensor. In a charge-coupled device, electrical charges are stored and transferred from an array of MOS capacitors. In a CMOS image sensor, there are a number of MOS transistors corresponding to the number of pixels and peripheral circuitry to sequentially output the electrical signals of the MOS transistors.

CMOS image sensors use CMOS technology to decrease feature size, power consumption, and fabrication costs and are applicable to such products as digital cameras, cellular telephones, personal digital assistants, notebook computers, bar-code readers, and toys. A CMOS image sensor is largely made up of a signal processing chip that includes an array of photodiodes provided with an amplifier, an analog-to-digital converter, an internal voltage regulator, a timing generator, and digital logic circuitry.

To enhance the photosensitivity of a CMOS image sensor, the fill factor of the CMOS image sensor may be improved. The photodiode area is increased with respect to the area of the device itself. The increase of the fill factor is limited, however, by the presence of the associated logic and signal processing circuitry of each photodiode. Enhanced photosensitivity may also be achieved by focusing incident light, which is deflected by, for example, a microlens provided to each photodiode to concentrate the incident light into the photodiode and away from the adjacent areas where there is no photodiode surface.

The focused light is thus directed through a color filter array, which includes an array of color filters arranged or patterned in the same layer according to color. In an exemplary embodiment, there are three colors, for example, red, green, and blue, or cyan, magenta, and yellow. Each color filter of the color filter array layer is a separate formation of a layer of colored resist, which is formed according to the pattern of the color filter array.

FIGS. 1-6 illustrate a conventional CMOS image sensor.

Referring to FIG. 1, the CMOS image sensor includes a unit pixel region, and a peripheral region of a pad portion. A field oxide film is formed by selective injection of boron into a silicon substrate to form a p-well 50 and an n-well and by applying a trench 60 device separating process. A gate oxide film of a predetermined thickness is then formed in accordance with a desired threshold voltage. A polysilicon film 40 and a tungsten silicide film 80 are formed as a gate oxide film to form a gate electrode of the device by selective etching. An n-ion injection region 20 and a p-ion injection region 10 are formed in the silicon substrate by selective ion injection to form a photodiode. To form a source and drain of a transistor having a lightly doped drain structure in a well region, source/drain ions are injected lightly, a tetra-ethyl-ortho-silicate (TEOS) oxide film or silicon nitride (SiN) is deposited by low-pressure chemical vapor deposition, and the entire surface of the resulting structure is etched to form spacers 70 at sidewalls of the gate electrode. Thereafter, source/drain ions are heavily injected to form an N-type junction region 30 and a P-type junction region.

Referring to FIG. 2, a TEOS oxide film, as a pre-metal dielectric layer 90, is formed by low-pressure chemical vapor deposition to a thickness of about 1000 Å, and borophosphosilicate glass is deposited on the TEOS oxide film by an atmospheric chemical vapor deposition, and is then heated to enable a state of flow. The pre-metal dielectric layer 90 is selectively etched to form a contact hole 100 that exposes a predetermined junction region and the gate electrode. A titanium layer 110 as a glue layer, aluminum layer 120 for wiring, and a non-reflective titanium nitride (TiN) layer 130 are each sequentially deposited and selectively etched to form a first metal line. The contact hole 100 is formed by plasma etching.

Referring to FIG. 3, a TEOS oxide film 150 and a spin-on glass oxide film 140 are formed by plasma-enhanced chemical vapor deposition, heat treated, and planarized. An oxide film, as a first inter-metal dielectric layer 160, is then formed by plasma-enhanced chemical vapor deposition.

Referring to FIG. 4, the first inter-metal dielectric layer 160 is etched selectively to form a via hole, and a second metal line is formed by plasma etching after again stacking titanium as a glue layer, aluminum for wiring, and a non-reflective titanium nitride. As in the formation of the first inter-metal dielectric layer 90, a TEOS oxide film 150, a spin-on glass oxide film 140, and an oxide film 160 are formed to form a second inter-metal dielectric layer, and any desired number of additional layers of metal wiring can be formed by repeating these steps.

Referring to FIG. 5, after formation of an uppermost metal wiring layer, an oxide film as a device protective film is formed by plasma-enhanced chemical vapor deposition to a thickness of about 8000 Å. A pad area for use as an electrode terminal is opened by etching the device protective oxide film and the titanium nitride film to expose a pad portion metal in a periphery.

Referring to FIG. 6, a color filter array 170 is formed on the resulting structure. A planarization layer 180 that provides a flat surface for receiving a microlens 190 is formed on the color filter array 170.

The above-described method, however, requires a separate planarizing step for forming the planarization layer 180, which complicates fabrication and increases costs accordingly. As such, this CMOS image sensor exhibits poor characteristics when operating at a relatively low luminance. Moreover, it is difficult to control the thickness of a resist layer that forms the color filter array.

### SUMMARY OF THE INVENTION

Accordingly, the present invention is directed to a CMOS image sensor and a method for fabricating the same that substantially obviates one or more problems that may be due to limitations and disadvantages of the related art.

The present invention provides a CMOS image sensor and a method for fabricating the same, which enables improved operating characteristics by filling a etched portion of a nitride film with a color filter material.

The present invention provides a CMOS image sensor and a method for fabricating the same, which simplifies fabrication by eliminating a planarization layer and reduces costs accordingly.

The present invention provides a CMOS image sensor and a method for fabricating the same, which enables a more precise control of the thickness of a resist layer by controlling the vertical disposition or depth of an etch stop layer.

Additional advantages, objects, and features of the invention will be set forth in part in the description which follows and will become apparent to those having ordinary skill in the art upon examination of the following. The invention may be realized and attained by the structure particularly pointed out in the written description and claims hereof as well as the appended drawings.

As embodied and broadly described herein, there is provided a CMOS image sensor comprising a passivation layer including an etch stop layer, the passivation layer having a color filter array pattern formed to a depth determined by the etch stop layer, the color filter array pattern including separately defined color filter regions; and a color filter array including a plurality of color filters for respectively filtering light according to color, the color filters being formed according to the color filter array pattern, each color filter formed of a material filling only a corresponding color filter region.

According to another aspect of the present invention, there is provided a method for fabricating a CMOS image sensor, the method comprising forming a passivation layer including an etch stop layer; etching the passivation layer to a depth determined by the etch stop layer according to a color filter array pattern including separately defined color filter regions; filling the separately defined color filter regions with a material for forming one color of a plurality of colors forming a color filter array; and removing the material filling the separately defined color filter regions corresponding to other colors of the plurality of colors of the color filter array.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention illustrate embodiments of the invention and together with the description serve to explain the principle of the invention. In the drawings:

FIGS. 1-6 are cross-sectional views of a conventional CMOS image sensor; and

FIGS. 7-11 are views of a CMOS image sensor according to the present invention.

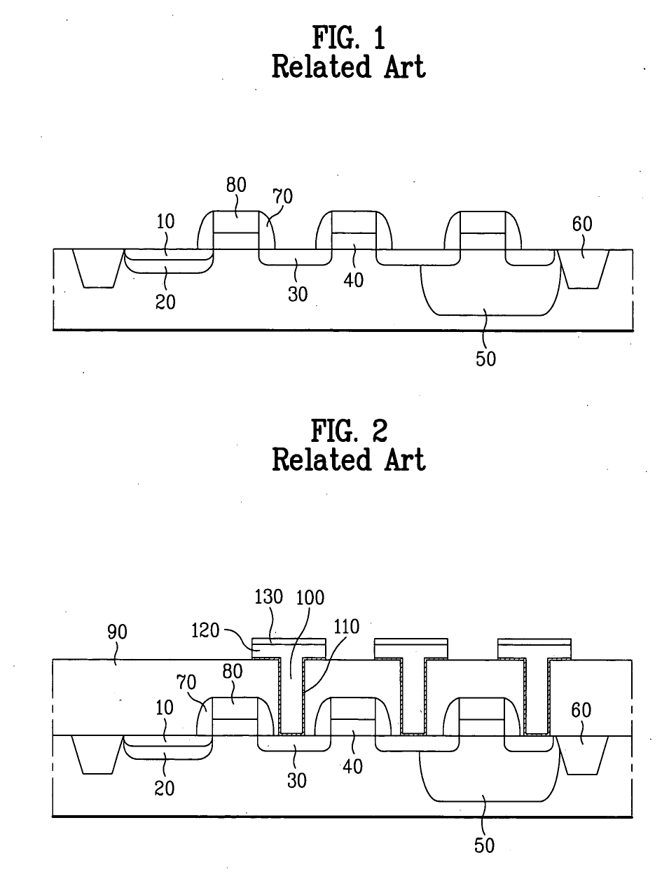

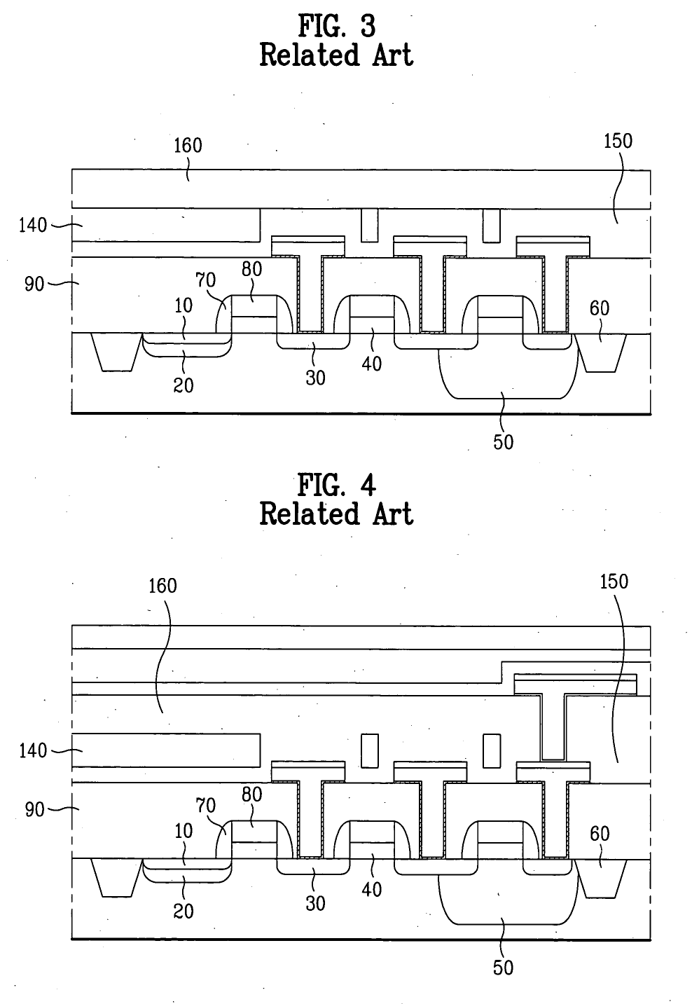

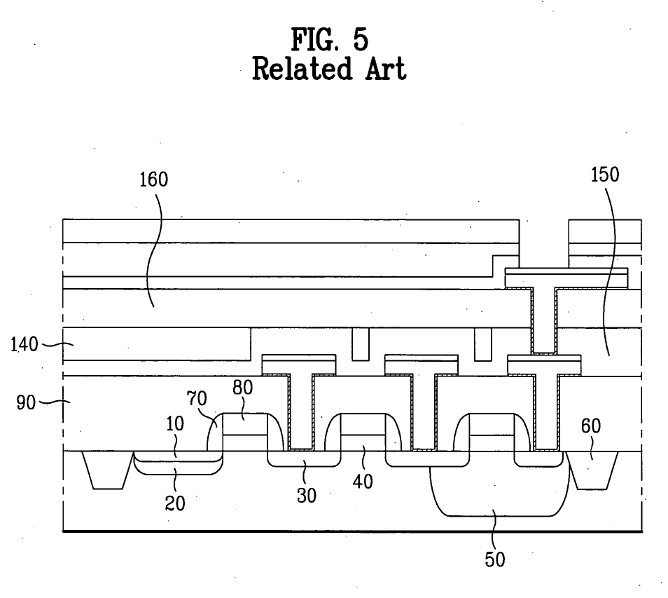

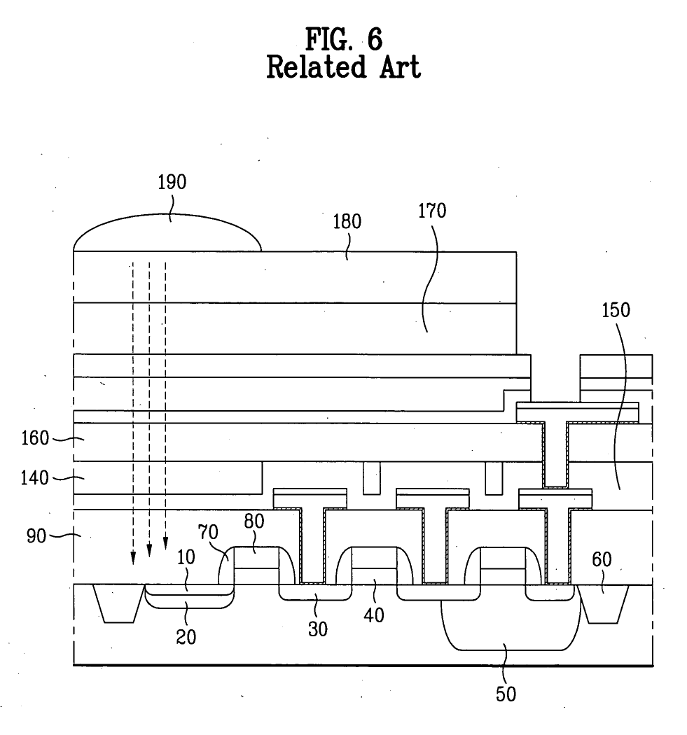

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

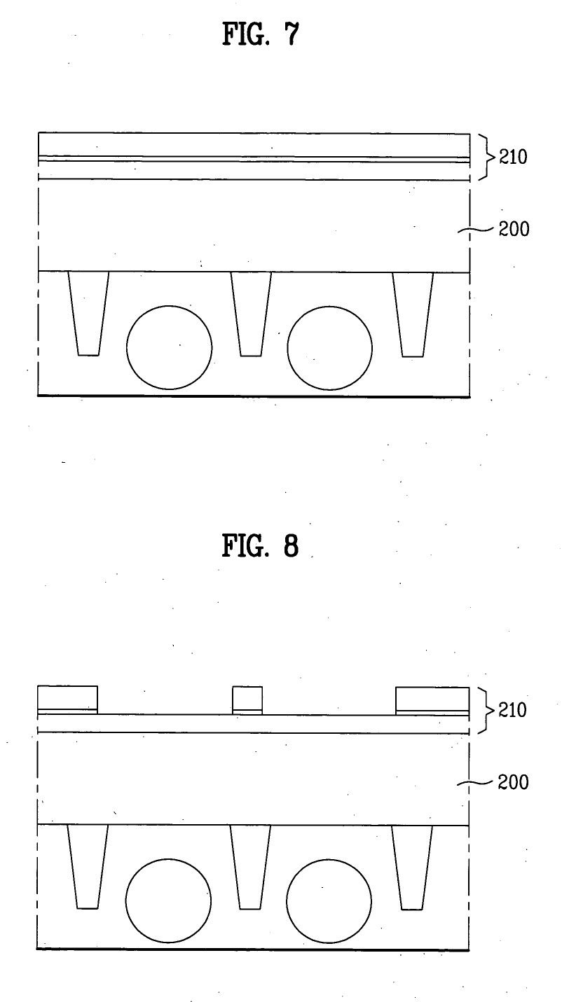

Referring to FIG. 7, a passivation layer 210 is formed on an insulating layer 200 of oxide/nitride or a substitute material covering a lower structure of a CMOS image sensor. An etch stop layer is included in the passivation layer 210. The etch stop layer is positioned at a depth determined by the amount of a color filter material used in a filling step to be described later and the desired thickness of the layer forming a color filter array. The color filter array can include a plurality of color filters for respectively filtering light according to color.

Referring to FIG. 8, the passivation layer 210 is selectively etched by a photo-etching process according to a pattern for forming the color filter array. In this case, only two regions are defined by the etching process, since only two of the necessary colors of a color filter array are shown, but the color filter array may include three or more colors, for example, red, green, and blue, or cyan, magenta, and yellow.

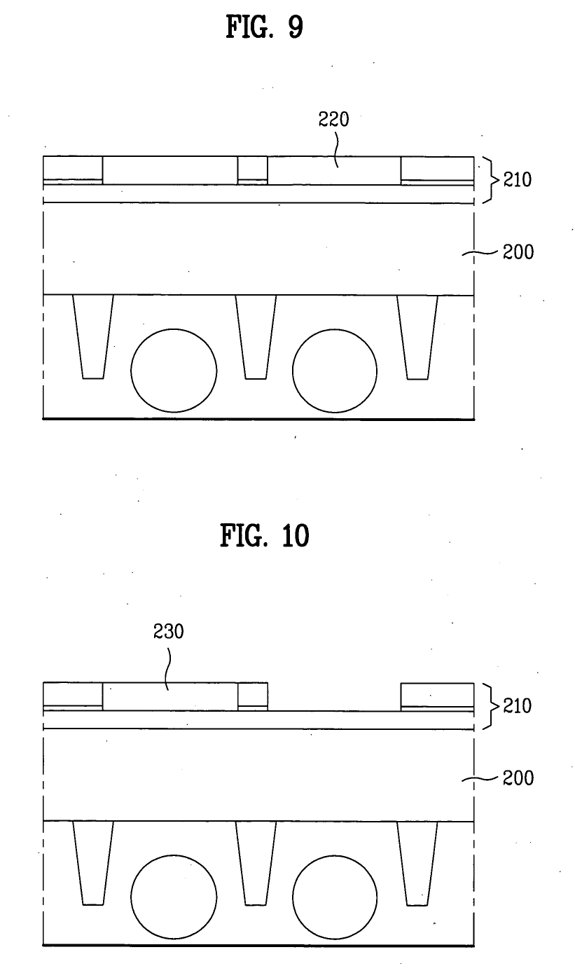

Referring to FIG. 9, a material 220, such as colored resist, for the formation of one of the colors of the color filter array is thickly deposited on the entire surface of the passivation layer, including the etched color filter regions to thereby fill the regions. The resulting deposition is planarized by, for example, chemical-mechanical polishing or an etch back process, taking an upper surface of the passivation layer as an end point, and leaving only the material in the etched color filter regions.

Referring to FIG. 10, the material filing the color filter regions of the other colors is removed, to leave only the material of a desired color, i.e., a first color filter 230. In other words, the material for the undesired color is removed. Removal may be achieved using an exposure and development process that uses a mask covering the desired color.

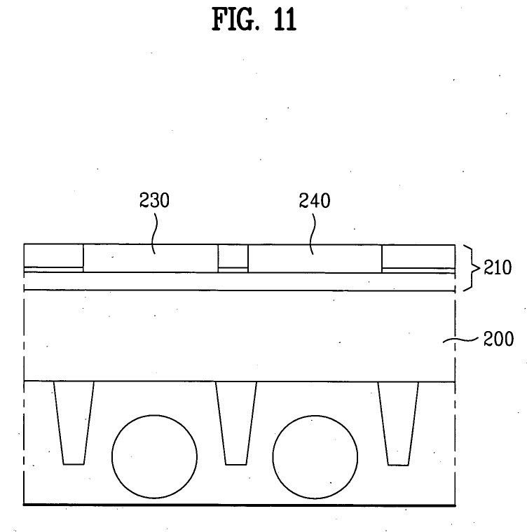

Referring to FIG. 11, the steps described with respect to FIGS. 9 and 10 are repeated for each color of the color filter array. For example, colored resist for the formation of an additional color of the color filter array is thickly deposited on the entire surface of the passivation layer, including the remaining (unfilled) color filter regions, to thereby fill the regions and form a second color filter 240. It should be appreciated that each of the first and second color filters 230 and 240 can be individual elements of one color filter of the overall array, which typically includes three different colors, e.g., red, green, and blue.

Accordingly, rather than forming the color filter by spin coating various colored resists and the exposure and development of each separate coating of the colored resists, which requires special equipment and processing, including the formation of a planarizing layer before carrying out the color filter forming process, the present invention can dispense with the planarizing process using a color filter material filling process, which simplifies fabrication while improving operation characteristics of a CMOS image sensor under low luminance conditions by reducing the amount of signal loss caused by an increased thickness due to the presence of the planarization layer. Moreover, by controlling the vertical disposition of an etch stop layer, specifically the depth at which its upper surface occurs within the passivation layer, the present invention can enable a more precise control of the desired thickness of the resist.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A CMOS image sensor, comprising:
a passivation layer including an etch stop layer, said passivation layer having a color filter array pattern formed to a depth in accordance with the etch stop layer, the color filter array pattern including separately defined color filter regions; and
a color filter array including a plurality of color filters for respectively filtering light according to color, the color filters being formed according to the color filter array pattern, each color filter formed of a material filling only a corresponding color filter region.

2. A CMOS image sensor according to claim 1, wherein the material of each color filter is a colored resist of one of the colors of the plurality of color filters.

3. A CMOS image sensor according to claim 1, further comprising an insulating layer covering a lower structure of the CMOS image sensor, said passivation layer being formed on said insulating layer.

4. A CMOS image sensor according to claim 1, wherein said color filter array includes three separate color filters.

5. A CMOS image sensor according to claim 4, wherein the colors of the plurality of color filters are red, green, and blue.

6. A CMOS image sensor according to claim 4, wherein the colors of the plurality of color filters are cyan, magenta, and yellow.

7. A method for fabricating a CMOS image sensor, comprising:
forming a passivation layer including an etch stop layer;
etching the passivation layer to a depth in accordance with the etch stop layer according to a color filter array pattern that includes separately defined color filter regions;
filling the separately defined color filter regions with a material for forming a first color of a plurality of colors forming a color filter array; and
removing the material filling the separately defined color filter regions corresponding to additional colors of the plurality of colors of the color filter array.

8. The method as claimed in claim 7, further comprising:
repeating said filling step and said removing step for each of the additional colors the plurality of colors of the color filter array.

9. The method as claimed in claim 7, wherein said removing step is achieved using an exposure and development process using a mask covering the color of said filling.

10. The method as claimed in claim 7, wherein the depth of said etching is in accordance with a desired thickness of the color filter array.
